(19) United States
(12) Patent Application Publication
(10) Pub. No.: US 2002/0108558 A1
(43) Pub. Date: Aug. 15, 2002

(54) Method for increasing charge size for single crystal silicon production

(76) Inventors: John Peter Hill, Moses Lake, WA (US); Jay Curtis Nelson, Moses Lake, WA (US); William John Juhasz JR., South Bend, IN (US); Henry Dare Wood, Moses Lake, WA (US)

Correspondence Address: KLARQUIST SPARKMAN, LLP, 121 SW SALMON STREET, SUITE 1600, PORTLAND, OR, 97204, US

(21) Appl. No.: 09/972,409

(22) Filed: Oct. 5, 2001

Related U.S. Application Data
(60) Provisional application No. 60/244,774, filed on Oct. 31, 2000.

(51) Int. Cl. C30B 15/00; C30B 13/00; C30B 28/08; C30B 27/02; C30B 30/04; C30B 28/10; C30B 21/06; C30B 21/04

(52) U.S. Cl. 117/37; 117/217; 117/218

(57) ABSTRACT

A system is disclosed for efficient utilization of charge replenishment rods in Czochralski silicon crystal growing processes.

### BACKGROUND

The present invention relates to improving the yield of single crystal silicon produced by the Czochralski (CZ) method. More particularly the invention relates to the hanging of charge replenishment rods in CZ furnaces.

Polycrystalline silicon is a critical raw material for the electronics industry. Polycrystalline silicon is the starting material for producing single crystal silicon ingots for the semiconductor industry. Approximately 90% of the semiconductor grade polycrystalline silicon is used in the Czochralski (CZ) method for the production of single crystal silicon ingot. These ingots are then shaped, sliced and polished to produce silicon wafers that are the major starting material for the semiconductor industry.

In the CZ crystal pulling technique, chunks of polycrystalline silicon are loaded into a quartz crucible. The chunks of polycrystalline silicon are random size, typically 1-4 inches in length. In addition, small chips, granules or short rod pieces of polycrystalline silicon may be added to the CZ crucible. Maximizing the packing density is a very critical issue. The crucible is filled to the top, loaded into a CZ furnace and the polycrystalline silicon is melted. Once the molten silicon is stabilized, a single crystal seed is brought into contact with the melt and a silicon ingot of specific diameter and orientation is pulled up from the melt. Upon melting of the polycrystalline silicon 20-30 percent of the crucible volume is vacant due to the limitations of packing the polycrystalline silicon in the quartz crucible.

Increased performance demanded of silicon based semiconductors has resulted in a reduction in the size and concentration of allowable defects in single crystal silicon ingots. This has resulted in changing of the design of the CZ furnaces and in particular the hot zone. For example, with the more modem CZ furnace growing an ingot having a diameter greater than or equal to 200 mm, it has become necessary to place a heat shield just above the crucible prior to melting the polycrystalline silicon. This heat shield is important for controlling the thermal gradient of the growing ingot. The relationship between thermal gradient and pull speed of the single crystal silicon has been identified as a critical parameter for controlling ingot defects and in particular, crystal oriented defects.

Unfortunately, the use of the heat shield just above the top of the crucible significantly reduces the amount of polycrystalline silicon that can be mounded above the top of the crucible during the loading process. If a heat shield was not required, an additional 10-30% polycrystalline silicon could be placed in the crucible. If polycrystalline silicon could be mounded above the top of the crucible during the loading process, molten silicon could occupy 70-80% of the volume of the crucible. With the heat shield in place, the level of the molten silicon is on the order of 50-70% of the crucible volume. Thus the use of the heat shield, which is critical for reducing defects in larger diameter ingots, has a serious economical impact on CZ crystal growing process.

In order to address the limitations that have been imposed upon the quality of single crystal silicon ingot, manufacturers of CZ ingots have tried several approaches for adding additional polycrystalline silicon to the melt. Granular or chip polycrystalline silicon can be added via a quartz tube. While this is a reasonable approach, both these silicon products have a high surface area and therefore have the potential for surface contamination. In addition many companies have difficulties getting good yield with granular polycrystalline silicon once it represents 10-20% of the total polycrystalline silicon charge.

Another approach has been to feed a suspended polycrystalline silicon rod into the melt to increase the volume of the molten silicon. In this approach a circumferential ring ditch is fabricated into the cylindrical surface of a polycrystalline silicon rod near one end of the rod. This ring ditch receives a mechanism attached to the seed holder of a CZ reactor such that the rod can be lowered into the melt using the cable or shaft to which the seed holder attaches. This allows an additional 10-35% polycrystalline silicon to be added to the melt. Using a polycrystalline silicon rod in this method is referred to as charge replenishment (CR). For example, using a 22-inch quartz crucible, 100 kg of polycrystalline silicon can be added with the initial crucible charge. A polycrystalline silicon rod of 35 kg can be melted to increase the total weight of molten silicon to 134 kg, thus increasing the silicon charge by 34%. (Approximately 1 kg is associated with an unmelted, leftover ring ditch piece.)

This method has significant limitations. For example, the polycrystalline rod is not completely utilized. The uppermost portion of polycrystalline rod that is attached via the ring ditch must be removed by pulling the cable or shaft to which it is attached up into the upper chamber of the CZ furnace, closing an isolation valve, opening the upper chamber, removing the residue polycrystalline silicon and then attaching the single crystal seed. The chamber is then closed, evacuated, the isolation valve opened, the seed lowered into the furnace chamber and once melt stabilization is complete the seed is dipped into the melt.

Each time the isolation valve is opened and closed there is the potential for contamination getting into the melt. With the quality requirements for single crystal silicon becoming tighter and tighter, this can be a very important issue in order to maintain the quality of the single crystal silicon ingot. cl SUMMARY

A system has been developed which allows for more efficient utilization of a CR polycrystalline rod in the CZ silicon crystal growing process. This will enable CZ silicon ingot manufacturers to increase their yields. In addition, in some embodiments, the CZ silicon ingot grower can reduce contamination by limiting the number of times they have to open and close the isolation valve.

### BRIEF DESCRIPTION OF THE DRAWINGS

In the drawings:

FIGS. 1A and 1B are schematic vertical cross-sectional views of a CZ furnace.

FIGS. 2A-2G are schematic vertical cross-sectional views depicting the current use of CR polycrystalline silicon rods.

FIG. 3A is a schematic vertical cross-sectional view of a keyhole system for hanging polycrystalline silicon rods.

FIG. 3B is a schematic vertical cross-sectional view of another keyhole system for hanging polycrystalline silicon rods.

FIG. 4 is a schematic cross-sectional view, taken along line 4-4 of FIG. 3A, showing a rod having a keyhole system of the type shown in FIG. 3A or FIG. 3B.

FIGS. 5A-5E are schematic vertical cross-sectional views depicting one embodiment of the use of polycrystalline silicon rods of the type shown in FIG. 3A.

### DETAILED DESCRIPTION

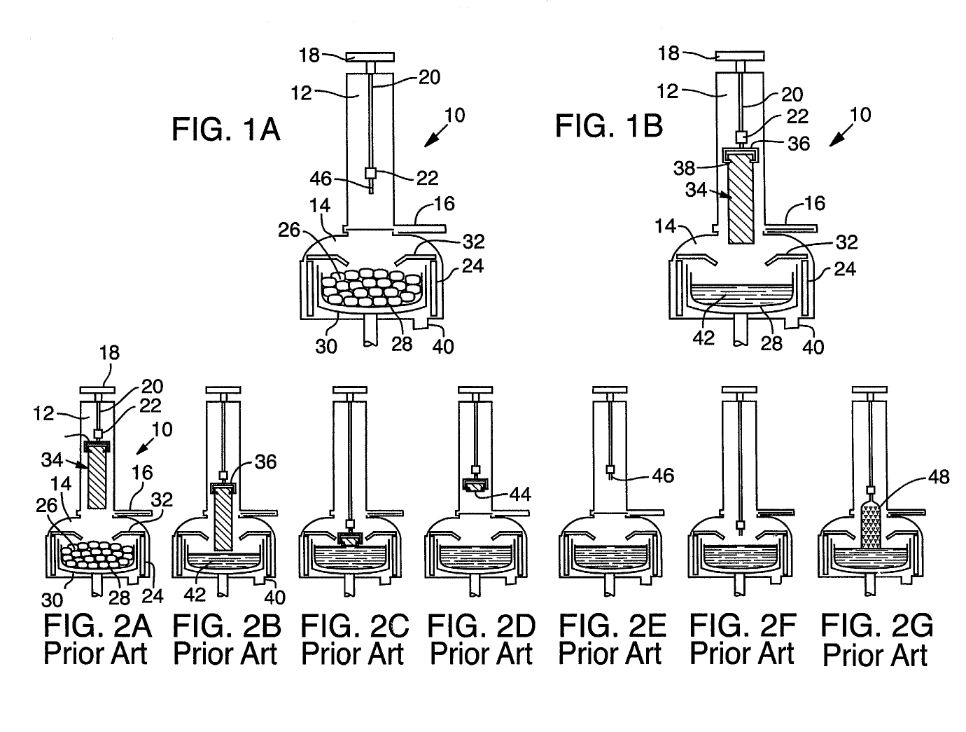

FIGS. 1A and 1B show the components of a typical CZ furnace. A CZ puller 10 has two parts, an upper chamber 12 and a lower furnace chamber 14. These two chambers are separated by an isolation valve 16. The puller 10 has a lift mechanism that includes a cable or shaft pulley system 18 in the upper chamber 12. The pulley system 18 is connected to a cable or shaft 20 that is used for raising or lowering silicon inside the puller 10. At the end of the cable or shaft is a seed holder 22, which can be used either to attach a CR rod to the cable or shaft, or to hold a single crystal silicon seed.

The lower furnace chamber 14, which can be isolated from the upper chamber 12 by the isolation valve 16, contains a heater 24 which is used to melt polycrystalline silicon chunks 26 inside a quartz crucible 28. The quartz crucible 28 can be raised or lowered within the heater by a succeptor 30. Depending on the type of single crystal silicon that is being grown, a heat shield 32 may be installed after the quartz crucible 28 is loaded with silicon chunks to be melted.

The normal operation of the CZ furnace with a ring ditched charge replenishment (CR) rod is shown sequentially in FIGS. 2A-2G. FIG. 2A shows the CZ furnace loaded with chunk polycrystalline silicon 26 in the quartz crucible 28 in the lower furnace chamber 14. A polycrystalline silicon rod 34 is attached to the seed holder 22 using a clamp or wire 36 that extends into a ring ditch 38 in the polycrystalline silicon rod 34 so that the rod hangs over the crucible. Both the upper and lower chambers 12, 14 are evacuated via a vacuum port 40 with the isolation valve 16 open.

The polycrystalline silicon chunk 26 is melted using the heater 24 to form a melt 42, that is a body of molten silicon. After the polycrystalline silicon chunk 26 is melted the polycrystalline silicon rod 34 is lowered into the lower furnace chamber 14 so that it can be preheated. FIG. 2B shows the position of the polycrystalline silicon rod 34 just prior to contact with the molten silicon 42. The polycrystalline silicon rod 34 is slowly lowered into the silicon melt 42 in a manner such that the melting rate of the rod 34 is faster than the lowering rate so that no appreciable amount of the rod is ever submerged in the melt 42.

The polycrystalline silicon rod 34 is melted from the bottom up to a level just below the ring ditch attachment 36 as shown in FIG. 2C. Contact between ring ditch attachment 36 and the silicon melt 42 is not allowed due to the potential for contamination. Therefore, the lowering is stopped prior to contact of the bottom of the ring ditch attachment 36 and the melt 42, so that a small portion 44 of the polycrystalline silicon rod 34 remains unmelted.

This unmelted portion 44 of the polycrystalline silicon rod 34 must then be raised up into the upper chamber 12 and the isolation valve 16 closed as is shown in FIG. 2D. The vacuum in the upper chamber 12 is released, the upper chamber opened and the remaining portion 44 of the polycrystalline silicon rod 34 is removed. A single crystal seed 46 is then attached to the seed holder 22 as shown in FIG. 2E. The upper chamber 12 is then evacuated, the isolation valve 16 opened and the single crystal seed 46 is lowered toward the silicon melt 42 as shown in FIG. 2F. Next the single crystal seed 46 is lowered into the silicon melt 42, whereafter the lift mechanism is reversed to start the pulling a single crystal silicon ingot 48 as shown in FIG. 2G.

This process requires that the isolation valve 16 be opened and closed twice during the crystal growth cycle. Each time this valve 16 is opened or closed it has the potential to allow impurities to fall into silicon melt 42. These impurities can lead to the formation of defects or loss of structure of the single crystal silicon, which will reduce the yield.

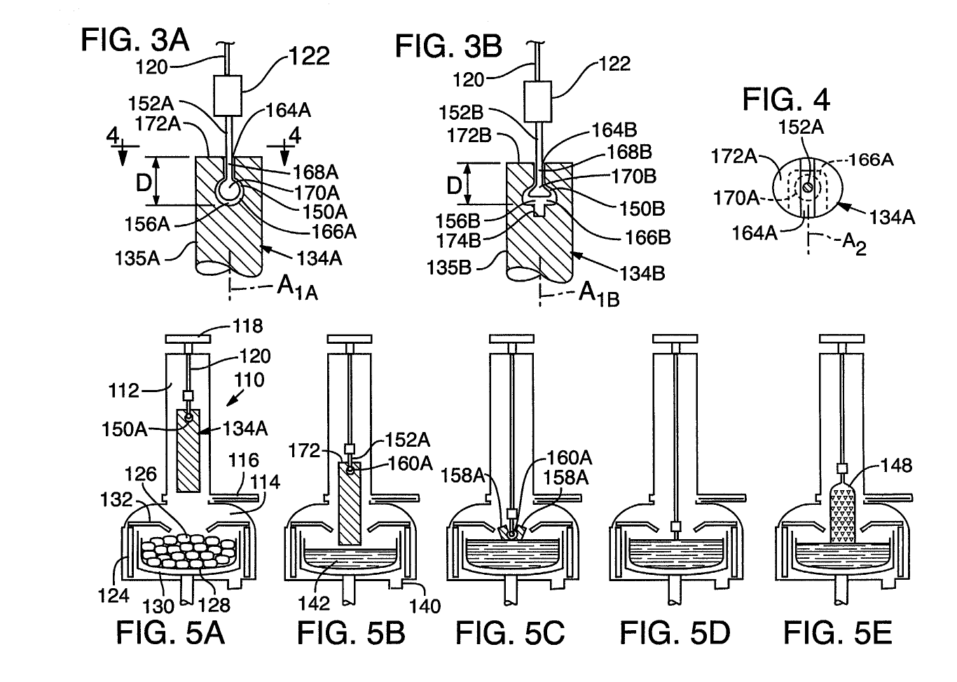

FIG. 3A and 3B show keyhole systems for attaching a CR rod to a seed holder. In FIGS. 3 and 4, elements that are similar to those shown in FIGS. 1 and 2 bear the same element numbers, but in those cases the numbers in FIGS. 3 and 4 are incremented by 100.

FIGS. 3A and 4 show a polycrystalline silicon rod 134A having a surface that includes a top surface 172A and a bottom surface, each of which has a generally circular perimeter and is generally planar, and a generally cylindrical side surface 135A that extends between the top and bottom surfaces. As used herein the terms “cylindrical” and “circular” should be taken in their broad senses. Although the term “circular” may be used herein, a typical polycrystalline silicon CR rod, as viewed from an end, is not perfectly circular, but is instead slightly elliptical in cross-section due to the ways in which such rods are grown. And the cross-section is not a mathematically perfect ellipse, but is somewhat irregular. A “cylindrical” rod could be any elongated rod having a side surface generally as traced by a straight line moving parallel to a fixed straight line and intersecting a fixed curve. The fixed curve need not be perfectly circular or perfectly elliptical. But as mentioned above, for commonly used CR rods, the fixed curve is typically a circle that is slightly out of round or slightly elliptical. Also, the side surface can vary somewhat from end-to-end of the rod. And a “planar” surface need not be perfectly flat.

The rod 134A is machined to provide a transversely extending, upwardly opening groove in the top surface 172A. The illustrated groove is a keyhole 150A located to extend generally horizontally through the rod when the rod is suspended. The keyhole 150A, as viewed from the side of a suspended rod in FIG. 3A, has a neck portion 164A and a body portion 166A located below the neck portion, with the neck portion 164A of a suspended rod being narrower horizontally than the body portion 166A. The illustrated body portion is generally circular in cross-section and has a longitudinal axis A₂. As can be seen in FIG. 4, the body portion 166A extends into the rod from only one location on the side surface 135A. Alternatively, the body portion could extend through the rod between two locations on the side surface 135A.

A rod hanger 152A is shaped to have a mating neck portion 168A and body portion 170A, with the neck portion being narrower horizontally than the body portion. The neck portion 168A of the rod hanger 152A is narrower horizontally than the neck portion 164A of the keyhole 150A of a suspended rod. And the body portion 170A of the rod hanger 152A is narrower horizontally than the body portion 166A of the keyhole 150A. But the body portion 170A of the rod hanger 152A is wider horizontally than the neck portion 164A of the keyhole 150A. Body portions 166A and 170A both can be generally circular, in vertical cross-section, with the diameter of body portion 170A being less than the diameter of body portion 166A.

The neck portion 164A of the keyhole 150A extends through the rod 134A and defines openings at two opposed locations on the cylindrical side surface 135A of the rod. As can be seen in FIG. 4, the neck portion 164A appears as a slot, or top of a channel, that extends across the top surface 172A of the rod between two locations on the perimeter of the top surface. Although the entire groove can extend between openings at two locations on the generally cylindrical surface 135A of the rod, lower portions of the groove need not extend all the way through. To simplify rod preparation, the body portion 166A of the keyhole 150A can be fabricated to extend only part way through the rod as best seen in FIG. 4.

Best results are achieved if the body portion 166A of the keyhole extends a sufficient distance inwardly from the generally cylindrical surface 135A of the rod that the rod holder 152A can be positioned near the center axis A_{1A} of the rod 134A. It is best to locate the keyhole 150A so that it extends through the central axis A_{1A} of the rod, because this makes it easiest to balance the rod to hang straight down. But a filament (not shown) located at the center axis A_{1A} of the rod may make it difficult to fabricate a keyhole through the center axis, in which case the keyhole could be located off center.

One or more additional keyholes and/or other types of slots (not shown) may also be provided in the top surface 172A, but such should not be necessary. This keyhole 150A is designed such that a rod hanger 152A will slide into hole 150A and act as a key to support the rod 134A. To balance the rod to hang down straight, the rod hanger 152A should be positioned as near the center axis A_{1A} of the rod as possible. The surface of the body portion 170A advantageously flares downwardly so that when the rod hanger 152A is received in the keyhole 150A of a rod and the rod is allowed to hang, the body portion 170A will wedgingly engage the rod due to the downward force of gravity.

The depth D and shape of the keyhole 150A are such that that of the bottom of the rod hanger 152A is located at an elevation above the bottom of the keyhole 150A when the rod 134A is supported by the rod hanger 152A. A gap 156A thus exists between the bottom of the rod hanger 152A and the bottom of the keyhole 150A. Due to the presence of the gap 156A, the polycrystalline rod 134A can be melted up to the level of the bottom of the keyhole that extends, at a level below the lift mechanism, between two locations on the surface of the rod. When the rod is sufficiently melted that an entire transversely extending bottom of the keyhole is melted, the remaining unmelted portion of the rod 134A consists of two or more separate pieces 158A of polycrystalline silicon, which pieces fall away from the rod hanger 152A by gravity and into the melt 142. One skilled in the art can determine the size and shape of the keyhole 150A, the rod hanger 152, and the gap 156A so as to prevent molten silicon from wicking into the keyhole during melting, which wicking might prevent separation of the pieces of the remaining unmelted portion of the rod 134A.

The fabrication of the keyhole is best done in a manner to prevent the generation of sharp comers, which give rise to stress risers and could cause the keyhole to fail under the weight of the rod 134A. One skilled in the art can determine fabrication techniques to prevent stress risers as well as the necessary radius of curvature of all corners and sharp edges to reduce formation of stress risers.

The grooves at the top of rods, including the keyhole 150A, are shown as being generally straight and to extend perpendicular to a plane that includes the rod axis A_{1A}. Such grooves are the easiest to fabricate, but it should be understood that other arrangements could be used. For example, the grooves could be slanted and/or could be not straight.

FIG. 3B shows a system that is similar to the system of FIG. 3A, except that in the system of FIG. 3B, the body portions 166B and 170B are generally triangular in vertical cross-section instead of being generally circular. And the entire groove of the rod shown in FIG. 3B extends substantially straight through the rod between two locations on the cylindrical side surface 135B. Thus the front of the rod 134B, as viewed parallel to the axis of the keyhole body portion 166B, is substantially a mirror image of the rear of the rod 134B, as viewed parallel to the axis of the keyhole body portion 166B. FIG. 3B also shows how the groove can have an extension slot 174B provided below the body portion 166B that extends between two locations on the surface of the rod. Such an added slot can be provided to accelerate the separation of residual rod parts. As the lift mechanism approaches the surface of a melt, the rod will melt up to the level of that portion of the groove that is the lowest open horizontal pathway between two locations on the surface of the rod, which pathway is provided by the extension slot 174B in the embodiment of FIG. 3B. At that point in the melting process, the remaining unmelted portion of the rod 134B consists of two or more separate pieces of polycrystalline silicon, which pieces fall away from the rod hanger 152B by gravity and into the melt.

In addition to the shapes shown in FIGS. 3A and 3B, other shapes can be used for the keyhole system such as a keyhole having a body portion of generally square or rectangular cross-section. The basic concept is to allow the connecting of the rod 152 to the polycrystalline rod 134 such that the rod can be centered on a rod hanger 152. The keyhole 150 is fabricated such that at least the neck portion provides a slot or hole that traverses a polycrystalline silicon rod 134 between two locations on the surface of the rod to provide an open space that extends between those locations and to the top of the rod, which allows the two sections 158 of the polycrystalline rod 134 to separate from the rod hanger 152 upon melting of the rod up to the lowest open horizontal pathway provided by the groove which divides the top portion of the rod. In addition, the body portion 166 of the keyhole 150 should be larger in dimensions than the body portion 170 of the rod hanger 152 so that a gap is provided therebetween, except for a small area at the top where the surface which defines the body portion 166 engages the surface of the body portion 170.

The rod hanger 152 can be made from a variety of materials such as quartz, Mo, W, polycrystalline silicon or single crystal silicon. The best material is single crystal silicon since it allows the user to fully benefit in terms of quality and yield.

This keyhole support system reduces the number of times the isolation valve 116 has to be opened and closed. In addition, it allows for complete utilization of the polycrystalline silicon rod 134 and improves cycle time by not having to open the upper chamber 112 during the crystal growing cycle. This improved process is illustrated in FIGS. 5A-5E.

FIG. 5A shows the CZ furnace loaded with polycrystalline silicon chunk 126 in the quartz crucible 128 in the lower furnace chamber 114. A heat shield 132 is shown in this case but is dependent on the type and quality of single crystal silicon to be grown. In the upper chamber 112 a polycrystalline silicon rod 134A is shown attached through the keyhole mechanism to the seed holder 152A with the top surface of the rod nearest the top of the furnace. The illustrated attachment between the seed holder 152A and the keyhole 150A in the polycrystalline silicon rod includes a single crystal seed 160A that matches the orientation of a single crystal ingot 148 to be grown. Both the upper and lower chambers 112, 114 are evacuated via the vacuum port 140 and the isolation valve 116 is opened.

The polycrystalline silicon chunk 126 is melted using the heater 124. As the polycrystalline silicon chunk 126 is being melted the polycrystalline silicon rod 134A is lowered into the lower chamber 114 so that it can be preheated. FIG. 5B shows the position of the polycrystalline silicon rod 134A just prior to contact with the molten silicon 142. The polycrystalline silicon rod 134A is slowly lowered into the silicon melt 142 in a manner that the melting rate is equal to or faster than the lowering rate.

The polycrystalline silicon rod 134A is lowered into the melt up to the bottom of the keyhole 150A in the polycrystalline silicon rod 134A which allows for two halves 158A of the remaining unmelted portion of the rod 134A to separate and fall into the silicon melt 142. This is shown in FIG. 5C. The single crystal seed 160A, as shown in FIG. 5D, is dipped into the melt 142 and the process of pulling a single crystal silicon ingot 148, as shown in FIG. 5E, can start. In some instances the charge replenishment steps and/or ingot pulling steps can be repeated during a single production run.

Providing a single crystal silicon seed, such as the seed 160A, as a portion of a rod hanger allows for a reduction in the overall cycle time of the CZ furnace. In addition, the threat of contamination is reduced because the number of times the isolation valve must be opened and closed is reduced. And finally, the complete polycrystalline silicon rod can be used which increases efficiency as well as control of the final molten silicon weight.

It will be apparent that many changes may be made in the above-described embodiments. For example, although it is most common for charge replenishment rods to be made of polycrystalline silicon, such rods could be made of single crystal silicon.

Thus single crystal silicon ingots that prove not to be suitable for wafer production could be machined and used as charge replenishment rods. And it will be appreciated that the bottom of an upwardly opening groove need not be perfectly flat. More importantly, the groove should be sufficiently deep that as the rod is melted from the bottom, the top of the rod separates into two or more pieces that fall into the melt. In the illustrated systems, a single crystal seed efficiently is provided as the lowermost part of the lift mechanism, but in other systems, a seed could also be provided in other ways such as by a drop-down mechanism. Also, although the illustrated embodiments show rods having top surfaces that are generally planar and that are perpendicular to the rod axis A₁, other embodiments could have other arrangements. For example, the top surface can extend at an angle to the axis A₁, such that the perimeter top surface is distinctly elliptical in general appearance as viewed perpendicularly to the surface. And if that angle is large enough, one end of the groove can be at the intersection of the groove with the top surface of the rod, instead of at the side surface of the rod. In such arrangements the rod holder may be received into a keyhole via an opening through the angled top surface. Therefore, the scope of the invention should be determined by the following claims.

1. A method for growing single crystal silicon, the method comprising:
providing a furnace having a crucible adapted to contain a melt and having a lift mechanism that can be operated to lower an object inside the furnace;
suspending a rod of silicon from the lift mechanism such that the rod hangs over the crucible, the rod having a surface including a generally cylindrical side surface and a top surface nearest the top of the furnace, the rod defining a transversely extending groove that opens upwardly at the top surface and that has a bottom that extends, at a level below the lift mechanism, between two locations on the surface of the rod;
operating the lift mechanism to lower the rod into the crucible;
applying heat, while the rod is being lowered, to melt at least the lowest portion of the rod; and
continuing to lower the rod until all that remains unmelted are separate rod pieces on opposite sides of the groove, which fall away from the lift mechanism and into a melt in the crucible.

2. The method of claim 1 wherein the groove is a keyhole that has a neck portion and a body portion located below the neck portion, with the neck portion being narrower horizontally than the body portion.

3. The method of claim 2 wherein:
the top surface has a generally circular perimeter; and
the keyhole extends through the rod such that the neck portion extends across the top surface of the rod between two locations on the perimeter of the top surface.

4. The method of claim 2 wherein the body portion of the keyhole extends into the rod from only one location on the side surface.

5.The method of claim 2 wherein the body portion of the keyhole extends between two locations on the surface of the rod.

6. The method of claim 5 wherein both of the two locations are on the side surface.

7. The method of claim 5 wherein the rod further defines an extension slot that extends downwardly from the body portion and that extends between two locations on the surface of the rod.

8. The method of claim 2 wherein the lift mechanism comprises a rod hanger that is received in the keyhole and that is shaped to have a neck portion and a body portion located below the neck portion with the neck portion of the rod hanger being narrower horizontally than the neck portion of the keyhole, the body portion of the rod hanger being narrower horizontally than the body portion of the keyhole, and the body portion of the rod hanger being wider horizontally than the neck portion of the keyhole so that the rod rests on the head portion of the rod hanger.

9. The method of claim 1 wherein:
the lift mechanism comprises a single crystal seed; and
the method further comprises operating the lift mechanism to dip the seed into the melt and then to raise the seed to pull a single crystal ingot from the melt.

10. The method of claim 9 wherein the single crystal seed is the lowermost portion of the lift mechanism that supports the rod.

11. A method for melting a silicon rod, the method comprising:
suspending a silicon rod from a suspension mechanism such that the rod hangs over a crucible, the rod having a surface including a generally cylindrical side surface and a top surface nearest the top of the furnace, the rod defining a transversely extending groove that opens upwardly at the top surface and that has a bottom that is
lower than the suspension mechanism that supports the rod;
lowering the rod into the crucible;
applying heat, while the rod is being lowered, to melt at least the lowest portion of the rod; and
continuing to lower the rod until all that remains unmelted are separate rod pieces on opposite sides of the groove, which fall away from the suspension mechanism and into the crucible.

12. The method of claim 11 wherein the groove is a keyhole that has a neck portion and a body portion located below the neck portion, with the neck portion being narrower horizontally than the body portion.

13. The method of claim 12 wherein:
the rod has a top surface that has a generally circular perimeter; and
the keyhole extends through the rod such that the neck portion extends across the top surface of the rod between two locations on the perimeter of the top surface.

14. The method of claim 12 wherein the body portion of the keyhole extends into the rod from only one location on the side surface.

15. The method of claim 12 wherein the body portion of the keyhole extends between two locations on the surface of the rod.

16. The method of claim 15 wherein both of the two locations are on the side surface.

17. The method of claim 16 wherein the rod further defines an extension slot that extends downwardly from the body portion of the keyhole and that extends between two locations on the surface of the rod.

18. The method of claim 12 wherein the lift mechanism comprises a rod hanger that is received in the keyhole and that is shaped to have a neck portion and a body portion located below the neck portion with the neck portion of the rod hanger being narrower horizontally than the neck portion of the keyhole, the body portion of the rod hanger being narrower horizontally than the body portion of the keyhole, and the body portion of the rod hanger being wider horizontally than the neck portion of the keyhole so that the rod rests on the head portion of the rod hanger.

19. A method for preparing a silicon rod, that has a surface including a generally cylindrical side surface and a top surface, for suspension in a furnace, the method comprising forming a transversely extending groove that extends across at least a portion of the top surface, at least a portion of the groove being a keyhole that has a neck portion that extends axially from the top surface and a body portion located axially inwardly from the neck portion, with the neck portion being narrower, as measured transversely, than the body portion.

20. The method of claim 19 further comprising:
forming the rod such that the top surface extends generally perpendicular to the longitudinal axis of the rod and has a generally circular perimeter; and
forming the keyhole to extend through the rod such that the neck portion extends across the top surface of the rod between two locations on the perimeter of the top surface.

21. The method of claim 19 further comprising forming the body portion of the keyhole to extend into the rod from only one location on the side surface.

22. The method of claim 19 further comprising forming the body portion of the keyhole to extend between two locations on the surface of the rod.

23. The method of claim 22 further comprising forming the body portion of the keyhole to extend between two locations on the side surface.

24. The method of claim 22 further comprising forming an extension slot that extends axially inwardly from the body portion and that extends between two locations on the surface of the rod.

25. Apparatus for growing single crystal silicon comprising:
a crucible adapted to contain a melt;
a lift mechanism located over the crucible;
a rod of polycrystalline silicon suspended from the lift mechanism such that the
rod hangs over the crucible, the rod having a free end nearest the crucible and an attached end at the top of the suspended rod, the rod defining a transversely extending groove that opens upwardly at the attached end, with the lift mechanism engaging the rod only at a level above the bottom of the groove; and
a heater positioned to heat the rod as the rod is lowered into the crucible by the lift mechanism.

26. The system of claim 25 wherein the groove is a keyhole that has a neck portion and a body portion located below the neck portion, with the neck portion being narrower horizontally than the body portion.

27. The system of claim 26 wherein:
rod has a top surface that has a generally circular perimeter; and
the keyhole extends through the rod such that the neck portion extends across the top surface of the rod between two locations on the perimeter of the top surface.

28. The system of claim 26 wherein the body portion of the keyhole extends into the rod from only one location on the surface of the rod.

29. The system of claim 26 wherein the body portion of the keyhole extends between two locations on the surface of the rod.

30. The system of claim 29 wherein the rod further defines an extension slot that extends downwardly from the body portion and that extends between two locations on the surface of the rod.

31. The system of claim 26 wherein the lift mechanism comprises a rod hanger that is received in the keyhole and that is shaped to have a neck portion and a body portion located below the neck portion, with the neck portion of the rod hanger being narrower horizontally than the neck portion of the keyhole, the body portion of the rod hanger being narrower horizontally than the body portion of the keyhole, and the body portion of the rod hanger being wider horizontally than the neck portion of the keyhole so that the rod rests on the head portion of the rod hanger.

32. The system of claim 26 wherein the lift mechanism comprises a single crystal seed.

33. The system of claim 32 wherein the single crystal seed is the lowermost portion of the lift mechanism that supports the rod.

34. A system for melting a silicon rod, the system comprising:
crucible adapted to contain a melt;
a lift mechanism located over the crucible;
a silicon rod suspended from the lift mechanism such that the rod hangs over the crucible, the rod having a free end nearest the crucible and an attached end at the top of the suspended rod, the rod defining a transversely extending groove that opens upwardly at the attached end, with the lift mechanism engaging the rod only at a level above the bottom of the groove; and
a heater positioned to heat the rod as the rod is lowered into the crucible by the lift mechanism.

35. The system of claim 34 wherein the groove is a keyhole that has a neck portion and a body portion located below the neck portion, with the neck portion being narrower horizontally than the body portion.

36. The system of claim 35 wherein:
the rod has a top surface that has a generally circular perimeter; and
the keyhole extends through the rod such that the neck portion extends across the top surface of the rod between two locations on the perimeter of the top surface.

37. The system of claim 35 wherein the body portion of the keyhole extends into the rod from only one location on the surface of the rod.

38. The system of claim 35 wherein the body portion of the keyhole extends between two locations on the surface of the rod.

39. The system of claim 38 wherein the body portion of the keyhole extends between two locations on the side surface.

40. The system of claim 35 wherein the rod further defines an extension slot that extends downwardly from the body portion and that extends between two locations on the surface of the rod.

41. The system of claim 35 wherein the lift mechanism comprises a rod hanger that is received in the keyhole and that is shaped to have a neck portion and a body portion located below the neck portion with the neck portion of the rod hanger being narrower horizontally than the neck portion of the keyhole, the body portion of the rod hanger being narrower horizontally than the body portion of the keyhole, and the body portion of the rod hanger being wider horizontally than the neck portion of the keyhole so that the rod rests on the head portion of the rod hanger.

42. A rod of silicon that:
has a generally cylindrical side surface;
has a top surface at one end of the side surface; and
defines a transversely extending groove that extends across at least a portion of the top surface, at least a portion of the groove being a keyhole that has a neck portion that extends axially inwardly from the top surface and a body portion located axially inwardly from the neck portion, with the neck portion being narrower, as measured transversely, than the body portion.

43. The rod of claim 42 wherein:
the rod has a top surface that has a generally circular perimeter; and
the keyhole extends through the rod such that the neck portion extends across the top surface of the rod between two locations on the perimeter of the top surface.

44. The rod of claim 42 wherein the body portion of the keyhole extends into the rod from only one location on the surface of the rod.

45. The rod of claim 42 wherein the body portion of the keyhole extends between two locations on the surface of the rod.

46. The system of claim 45 wherein the body portion of the keyhole extends between two locations on the side surface.

47. The rod of claim 45 wherein the rod further defines an extension slot that extends axially inwardly from the body portion and that extends between two locations on the surface of the rod.
